(19) United States
(12) Patent Application Publication
(10) Pub. No.: US 2011/0308844 A1
(43) Pub. Date: Dec. 22, 2011

(54) Conductive electrode pattern and solar cell with the same

(75) Inventors: Kyoung-Jin Jeong, Suwon-si (KR); Sung Il Oh, Seoul (KR); Jae Woo Joung, Suwon-si (KR); Da Mi Shim, Suwon-si (KR)

(73) Assignee: Samsung Electro-Mechanics Co., Ltd., Suwon (KR)

(21) Appl. No.: 12/926,336

(22) Filed: Nov. 10, 2010

(30) Foreign Application Priority Data
Jun. 21, 2010 (KR) 10-2010-0058609

(51) Int. Cl. H05K 1/09; H01L 31/0224; H01B 5/00

(52) U.S. Cl. 174/257; 174/126.2; 136/256

(57) ABSTRACT

Disclosed herein is a conductive electrode pattern used as an electrode of a solar cell. The conductive electrode pattern includes a lower metal layer and an upper metal layer vertically disposed on a substrate, wherein any one of the lower metal layer and the upper metal layer includes silver (Ag) and the other one of the lower metal layer and the upper metal layer includes a metal of transition metals, different from that of the lower metal layer.

### CROSS REFERENCE TO RELATED APPLICATION

This application claims the benefit of Korean Patent Application No. 10-2010-0058609, filed on Jun. 21, 2010, entitled “Conductive Electrode Pattern And Solar Cell With The Same”, which is hereby incorporated by reference in its entirety into this application.

### BACKGROUND OF THE INVENTION

1. Technical Field

The present invention relates to a conductive electrode pattern and a solar cell with the same, and more particularly, to a conductive electrode pattern used as an electrode wiring of a solar cell and a solar cell with the same.

2. Description of the Related Art

Generally, an electrode of a solar cell includes a silicon substrate having a light receiving surface, and a conductive electrode pattern disposed on the light receiving surface of the silicon substrate. The conductive electrode pattern is disposed on the light receiving surface, such that as a line width of the conductive electrode pattern is reduced, the actual incidence of light on the light receiving surface is relatively increased. Therefore, the reduction of the line width in the conductive electrode pattern is important in improving energy conversion efficiency of a solar cell. However, as the line width of the conductive electrode pattern is reduced, electric resistance of the conductive electrode pattern is increased, such that electrode characteristics are degraded. Therefore, the conductive electrode pattern of the solar cell should simultaneously satisfy the fine line width and the characteristics of high electrical conductivity.

Currently, as a method of forming a conductive electrode pattern of a solar cell, a screen printing method printing silver (Ag) paste on an electrode forming region of a silicon substrate has been most widely used.

However, the screen printing method using Ag paste described above uses silver (Ag), a relatively expensive metal ion, thereby increasing manufacturing costs of a solar cell. In particular, a conductive electrode pattern of a solar cell is required to have a fine line width, such that a thickness of the conductive electrode pattern should be relatively increased in order to ensure electrical conductivity of the conductive electrode pattern. To this end, the thickness of the conductive electrode pattern has currently increased by repeatedly printing Ag paste on the same region of a silicon substrate. Therefore, a large amount of Ag paste is used in order to form the conductive electrode pattern of the solar cell according to the related art, thereby increasing manufacturing costs of the solar cell.

In addition, the screen printing method applies physical pressure on the silicon substrate, such that the silicon substrate is most likely to be damaged. In particular, with the increasing demand for integration and reduction in costs of a solar cell, there has been an attempt to reduce unit cost of the silicon substrate, which is a large expenditure in consideration of manufacturing costs of the solar cell. In order to reduce the unit cost of the silicon substrate, a thickness of the silicon substrate should be substantially reduced. However, when the silicon substrate has a thin thickness, the silicon substrate may be broken due to physical pressure at the time of the screen printing process, such that there is a technical limitation in reducing the thickness of the silicon substrate. Currently, when the conductive electrode pattern is formed by the screen printing method, it has been known that the minimum thickness of the silicon substrate is approximately 180 μm so as to prevent the damage due to the physical pressure.

### SUMMARY OF THE INVENTION

An object of the present invention is to provide a conductive electrode pattern improving electrode characteristics of a solar cell and a solar cell with the same.

Another object of the present invention is to provide a conductive electrode pattern reducing manufacturing costs and a solar cell with the same.

Another object of the present invention is to provide a conductive electrode pattern having a structure capable of preventing the damage of a substrate at the time of forming the conductive electrode pattern and a solar cell with the same.

According to the exemplary embodiment of the present invention, there is provided a conductive electrode pattern, including: a lower metal layer and an upper metal layer that are vertically disposed on a substrate, wherein any one of the lower metal layer and the upper metal layer includes silver (Ag) and the other one of the lower metal layer and the upper metal layer includes a metal of transition metals, different from that of the lower metal layer.

The lower metal layer may include silver, and the upper metal layer may include at least any one of titanium (Ti), vanadium (V), chrome (Cr), manganese (Mn), iron (Fe), cobalt (Co), nickel (Ni), copper (Cu), silver (Ag), gold (Au), and iron (Fe).

The lower upper metal layer may be formed by using the lower metal layer as a seed layer.

The conductive electrode pattern may further include an organic compound thin layer interposed between the upper metal layer and the upper metal layer.

The organic compound thin layer may include an organic acid. The organic compound thin layer may include at least any one of oxalic acid, oxalacetic acid, fumaric acid, malic acid, succinic acid, acetic acid, butyric acid, palmitic acid, tartaric acid, ascorbic acid, uric acid, sulfonic acid, sulfinic acid, phenol, formic acid, citric acid, isocitric acid, α-ketoglutaric acid, succinic acid, and nucleic acid.

The conductive electrode pattern may further include a barrier layer interposed between the lower metal layer and the upper metal layer.

The barrier layer may include nickel (Ni).

The barrier layer may be a plating layer formed by using the lower metal layer as a seed layer.

The conductive electrode pattern may further include a top metal layer that is stacked on the upper metal layer, wherein the top metal layer may be used as a medium for connecting the conductive electrode pattern to an external electronic apparatus.

The top metal layer may include tin (Sn).

The top metal layer may be a plating layer formed by using the upper metal layer as a seed layer.

According to the exemplary embodiment of the present invention, there is provided a conductive electrode pattern used as an electrode of a solar cell, wherein the conductive electrode pattern has a hetero-metal layer stacking structure formed of different metal layers.

The hetero-metal layer, stacking structure may include metal layers made of different metals among transition metals.

The hetero-metal layer stacking structure may include: a silver (Ag) layer disposed adjacent to the silicon substrate; and a copper (Cu) layer stacked on the silver layer, wherein the thickness of the silver layer may be thinner than that of the copper layer.

The hetero-metal layer stacking structure may further include a nickel layer interposed between the silver layer and the copper layer, wherein the thickness of the nickel layer may be thicker than that of the silver layer and be thinner than that of the copper layer.

The hetero-metal layer stacking structure may further include a tin layer that covers the copper layer, wherein the thickness of the tin layer may be thicker than that of the silver layer and be thinner than that of the copper layer.

The hetero-metal layer stacking structure may include metal layers made of different metals and stacked each other, wherein a bottom metal layer of the metal layers is a metal layer formed by applying a conductive ink, and metal layers disposed on the bottom metal layer among the metal layers are plating layers formed by using metal layers below the metal layers as seed layers.

The hetero-metal layer stacking structure may include: metal layers made of different metals; and an organic compound thin layer interposed between the metal layers, wherein the organic compound thin layer includes an organic acid.

The organic acid may include at least any one of oxalic acid, oxalacetic acid, fumaric acid, malic acid, succinic acid, acetic acid, butyric acid, palmitic acid, tartaric acid, ascorbic acid, uric acid, sulfonic acid, sulfinic acid, phenol, formic acid, citric acid, isocitric acid, α-ketoglutaric acid, succinic acid, and nucleic acid.

According to the exemplary embodiment of the present invention, there is provided a solar cell, including: a substrate that has a light receiving surface on which an external light is incident; and a conductive electrode pattern that is disposed on the light receiving surface of the substrate, wherein the conductive electrode pattern is formed of different metal layers.

Any one of the metal layers may include silver (Ag), and others of the metal layers may include any one of titanium (Ti), vanadium (V), chrome (Cr), manganese (Mn), iron (Fe), cobalt (Co), nickel (Ni), copper (Cu), silver (Ag), gold (Au), iron (Fe), tin (Sn), lead (Pb), and zinc (Zn).

The metal layers may include: a silver (Ag) layer that is disposed adjacent to the silicon substrate; and a copper (Cu) layer that is stacked on the silver layer, wherein the thickness of the silver layer may range from 0.1 μm to 3 μm, and the thickness of the copper layer may range from 25 μm to 29 μm.

The metal layers may further include a nickel layer that is interposed between the silver layer and the copper layer, wherein the thickness of the nickel layer may range from 2 μm to 5 μm.

The metal layers may further include a tin layer that covers the copper layer, wherein the thickness of the tin layer may range 0.5 μm to 2.5 μm.

A bottom metal layer of the metal layers may be a metal layer formed by applying a conductive ink onto the substrate, and metal layers stacked on the bottom metal layer among the metal layers mat be plating layers formed by using metal layers below the metal layers as seed layers.

A thickness of the substrate may be 180 μm or less, a line width of the conductive electrode pattern may be 80 μm or less, and a thickness of the conductive electrode pattern may be 30 μm or less.

The hetero-metal layer stacking structure may include organic compounds thin layer interposed between the metal layers, wherein the organic compound thin layer may include an organic acid.

The organic acid may include at least any one of oxalic acid, oxalacetic acid, fumaric acid, malic acid, succinic acid, acetic acid, butyric acid, palmitic acid, tartaric acid, ascorbic acid, uric acid, sulfonic acid, sulfinic acid, phenol, formic acid, citric acid, isocitric acid, α-ketoglutaric acid, succinic acid, and nucleic acid.

### BRIEF DESCRIPTION OF THE DRAWINGS

FIG. 1 is a diagram showing a partial configuration of a solar cell according to an embodiment of the present invention;

FIG. 2 is a flow chart showing a method for manufacturing a solar cell according to the present invention; and

FIGS. 3 to 6 are diagrams for explaining a method for manufacturing a solar cell according to the present invention.

### DESCRIPTION OF THE PREFERRED EMBODIMENTS

Various advantages and features of the present invention and methods accomplishing thereof will become apparent from the following description of embodiments with reference to the accompanying drawings. However, the present invention may be modified in many different forms and it should not be limited to the embodiments set forth herein. Rather, these embodiments may be provided so that this disclosure will be thorough and complete, and will fully convey the scope of the invention to those skilled in the art. Like reference numerals in the drawings denote like elements.

Terms used in the present specification are for explaining the embodiments rather than limiting the present invention. Unless explicitly described to the contrary, a singular form includes a plural form in the present specification. The word “comprise” and variations such as “comprises” or “comprising,” will be understood to imply the inclusion of stated constituents, steps, operations and/or elements but not the exclusion of any other constituents, steps, operations and/or elements.

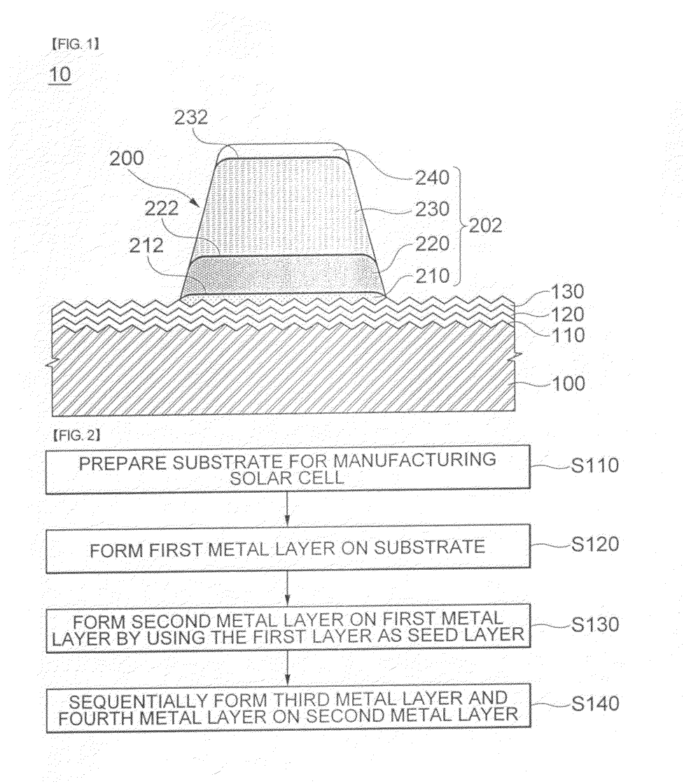

FIG. 1 is a diagram showing a partial configuration of a solar cell according to an embodiment of the present invention. Referring to FIG. 1, a solar cell according to an embodiment of the present invention may be configured to include a substrate 100 and a conductive electrode pattern 200 that is disposed on the substrate 100.

The substrate 100 may be a plate for manufacturing the solar cell 10. As an example, the substrate 100 may be a silicon wafer. The substrate 100 may have a light receiving surface 110 on which an external light is incident. The light receiving surface 110 is textured, thereby having a predetermined rugged structure. A PN junction layer 120 and a transparent electrode layer 130 may be sequentially formed on the light receiving surface 110. The PN junction layer 120 may be formed by injecting an N-type semiconductor layer onto a P-type silicon wafer.

The transparent electrode layer 130 may include a transparent conductive oxide (TCO) that covers the PN junction layer 120. The transparent electrode layer 130 may include at least any one of zinc oxide (ZnO), tin oxide (SnO), indium tin oxide (ITO), and indium tungsten oxide (IWO).

Meanwhile, the substrate 100 may have a minimum thickness in order to minimize manufacturing costs of the substrate 100, so far as not to degrade efficiency in the process of forming the conductive electrode pattern 200. For example, when the substrate 100 is a silicon wafer, the thickness of the substrate 100 may be controlled to be 180 μm or less. When the thickness of the substrate 100 is 180 μm or more, the thickness of the substrate 100 becomes thick and the used amount of silicon is increased, such that manufacturing costs of the substrate 100 may be increased. In addition, as the thickness of the substrate 100 is increased, the integration of the solar cell 10 may be lowered. Therefore, it may be preferable that the thickness of the substrate 100 is controlled to be 180 μm or less in order to reduce manufacturing costs of the solar cell 10 and improve integration thereof.

The conductive electrode pattern 200 may be a configuration that is used as an electrode wiring of the solar cell 10. The conductive electrode pattern 200 may have a hetero-metal layer stacking structure 202 formed of different kinds of metal layers. For example, the hetero-metal layer stacking structure 202 may have a multi-layer structure formed of different metal layers selected from transition metals and other metal ions. More specifically, the hetero-metal layer stacking structure 202 may include metal layers including at least any one of titanium (Ti), vanadium (V), chrome (Cr), manganese (Mn), iron (Fe), cobalt (Co), nickel (Ni), copper (Cu), silver (Ag), gold (Au), and iron (Fe). In addition, the hetero-metal layer stacking structure 202 may include metal layers made of non-transition metals such as tin (Sn), lead (Pb), and zinc (Zn).

For example, the hetero-metal layer stacking structure 202 may include first to fourth metal layers 210, 220, 230 and 240 which are sequentially stacked on the substrate 100. The first metal layer 210 may be disposed to be most adjacent to the substrate 100 as compared to the second to fourth metal layers 220, 230 and 240. In other words, the first metal layer 210 may be the bottom metal layer. The first metal layer 210 may include metal ions with the most expensive raw material as compared to the second to fourth metal layers 220, 230 and 240. As an example, the first metal layer 210 may be a conductive layer including silver (Ag). The first metal layer 210 may be used as a seed layer for forming the second metal layer 220.

The second metal layer 220 may cover the first metal layer 210. The second metal layer 220 may be a conductive layer that includes any one of the remaining transition metals except silver (Ag). As an example, the second metal layer 220 may be a plating layer including nickel (Ni). The second metal layer 220 is interposed between the first metal layer 210 and the third metal layer 230, thereby being used as a barrier layer that reduces an electrical effect between the first and second metal layers 210 and 230.

The third metal layer 230 may cover the second metal layer 220. The third metal layer 230 may be a conductive layer that includes any one of the remaining transition metals except silver (Ag). As an example, the third metal layer 230 may be a plating layer including copper (Cu). The third metal layer 230 may mainly function as an electrode of the conductive electrode pattern 200 in view of functional aspect. In other words, the third metal layer 230 may be a metal layer that mainly functions as an electrode wiring, among the first to fourth metal layers 210, 220, 230, and 240. Therefore, the third metal layer 230 may occupy the largest volume in the conductive electrode pattern 200.

The fourth metal layer 240 may be disposed on the top layer of the conductive electrode pattern 200. In other words, the fourth metal layer 240 may be the top metal layer. The fourth metal layer 240 may cover the third metal layer 230. The fourth metal layer 240 may be a conductive layer that includes any one of the remaining transition metals except silver (Ag). As an example, the fourth metal layer 240 may be a conductive layer including tin (Sn). In this case, the fourth metal layer 240 may be used as a medium for electrically connecting the conductive electrode pattern 200 to a connection unit such as a solder ball, a bonding wire, or the like.

Predetermined organic compound thin layers may be interposed between the first to fourth metal layers 210, 220, 230, and 240. For example, the conductive electrode pattern 200 may further include a first organic compound thin layer 212 interposed between the first and second metal layers 210 and 220, a second organic compound thin layer 222 interposed between the second and third metal layers 220 and 230, and a third organic compound thin layer 232 interposed between the third and fourth metal layers 230 and 240.

The first to third organic compound thin layers 212, 222, and 232 may be carboxylic acid based organic compounds. For example, the first to third organic compound thin layers 212, 222, and 232 may be any one of various kinds of organic acids. More specifically, each of the first to third organic compound thin layers 212, 222, and 232 may include at least any one of oxalic acid, oxalacetic acid, fumaric acid, malic acid, succinic acid, acetic acid, butyric acid, palmitic acid, tartaric acid, ascorbic acid, uric acid, sulfonic acid, sulfinic acid, phenol, formic acid, citric acid, isocitric acid, α-ketoglutaric acid, succinic acid, and nucleic acid. Meanwhile, the first to third organic compound thin layers 212, 222, and 232 may further include at least any one of ammonia compounds and water in addition to the organic acids.

Herein, the first to third organic compound thin layers 212, 222, and 232 may be provided as the same organic acid thin layers. Alternatively, the kind of the first to third organic compound thin layers 212, 222, and 232 may be different in consideration of material properties of the first to fourth metal layers 210, 220, 230, and 240.

Meanwhile, the relative thickness of the first to fourth metal layers 210, 220, 230, and 240 may be controlled according to each function thereof. For example, the first metal layer 210 may have a thickness thinner than the second to fourth metal layers 220, 230, and 240. As an example, when the total thickness of the conductive electrode pattern 200 is approximately 30 μm and the line width thereof is approximately 80 μm, the thickness of the first metal layer 210 may be controlled to be approximately 0.1 μm to 3 μm. When the thickness of the first metal layer 210 is thinner than 0.1 μm, its function as a seed layer for forming the second metal layer 220 may be degraded. To the contrary, when the thickness of the first metal layer 210 exceeds 3 μm, the used amount of the first metal layer 210 is increased, such that costs for manufacturing the conductive electrode pattern 200 may be increased. The object of the present invention is to reduce manufacturing costs of the conductive electrode pattern 200, such that it may be preferable to reduce the used amount of the first metal layer 210, which is relatively the most expensive. To this end, the thickness of the first metal layer 210 may be provided at the minimum thickness but capable of ensuring the function of the seed layer.

The thickness of the second metal layer 220 may be controlled to be a minimum thickness but capable of functioning as the barrier layer. For example, the thickness of the second metal layer 220 may be controlled to be approximately 2 μm to 5 μm. When the thickness of the second metal layer 220 is thinner than 2 μm, its function as the barrier layer may be degraded. To the contrary, when the thickness of the second metal layer 220 exceeds 5 μm, the thickness of the second metal layer 220 becomes unnecessarily thick, such that the total thickness of the conductive electrode pattern 200 may be increased.

The third metal layer 230 mainly functions as an electrode wiring in the conductive electrode pattern 200, such that the third metal layer 230 may occupy the largest volume in the total thickness of the conductive electrode pattern 200. For example, the thickness of the third metal layer 230 may be controlled to be approximately 25 μm to 29 μm. Therefore, the conductive electrode pattern 200 may have a structure in which the volume of the copper layer (third metal layer: 230) is remarkably increased as compared to that of the silver layer (first metal layer: 210).

The fourth metal layer 240 may be used as a medium for connecting the conductive electrode pattern 200 to the outside. In this case, the fourth metal layer 240 may hardly function as an actual electrode, such that the thickness of the fourth metal layer 240 may be controlled to be a minimum thickness but capable of functioning as the medium. For example, the thickness of the fourth metal layer 240 may be controlled to be approximately 0.5 μm to 2.5 μm. When the thickness of the fourth metal layer 240 is thinner than 0.5 μm, its function as the medium to be connected to the outside may be degraded. To the contrary, when the thickness of the fourth metal layer 240 exceeds 2.5 μm, the thickness of the fourth metal layer 240 becomes unnecessarily thick, such that the total thickness of the conductive electrode pattern 200 may be increased.

In the conductive electrode pattern 200 having the structure as described, a thickness ratio of the first to fourth metal layers 210, 220, 230, and 240 may be controlled to be close to approximately 1:10:100:5. The conductive electrode pattern 200 having the structure as described above can minimize the content of silver (Ag), which is relatively expensive. In addition, the conductive electrode pattern 200 can have a minimum thickness on condition that the electrode characteristics of the conductive electrode pattern 200 are ensured.

As described above, the solar cell 100 according to an embodiment of the present invention includes the conductive electrode pattern 200 provided on the substrate 100, wherein the conductive electrode pattern 200 may have the hetero-metal layer stacking structure 202 formed of different kinds of metal layers 210, 220, 230, and 240. Herein, the metal layer stacking structure 202 may have a structure in which the content of the silver layer (that is, first metal layer 210), which is expensive, is decreased and the content of the copper layer (that is, third metal layer 230), which is relatively inexpensive and has excellent electrical conductivity, is increased, while maintaining the electrode characteristics. Therefore, the solar cell 10 according to the present invention can reduce the manufacturing costs thereof, while maintaining or further improving the electrode characteristics of the conductive electrode pattern 200.

In addition, the solar cell 10 according to an embodiment of the present invention may have a structure in which the thickness of the substrate 100 is decreased. In particular, the present invention has a structure in which the thickness of silicon wafer for manufacturing the solar cell 10 is decreased to be 180 μm or less, thereby making it possible to reduce the used amount of silicon. Therefore, the solar cell 10 according to the present invention includes the substrate 100 having a minimum thickness on which the conductive electrode pattern 200 can be formed, thereby making it possible to increase integration and reduce the manufacturing costs thereof.

Hereinafter, a method for manufacturing the solar cell according to the present invention will be described in detail. Herein, a description overlapping with the aforementioned solar cell 10 may be omitted or simplified.

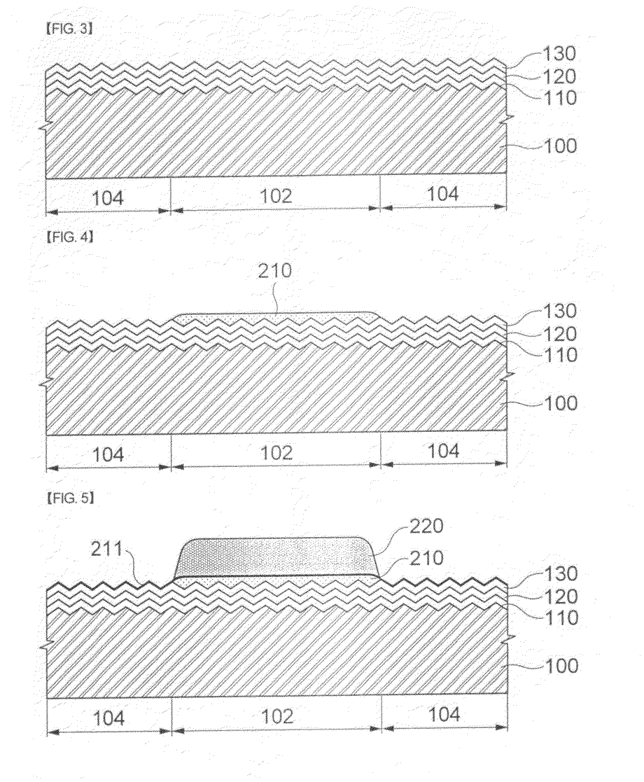

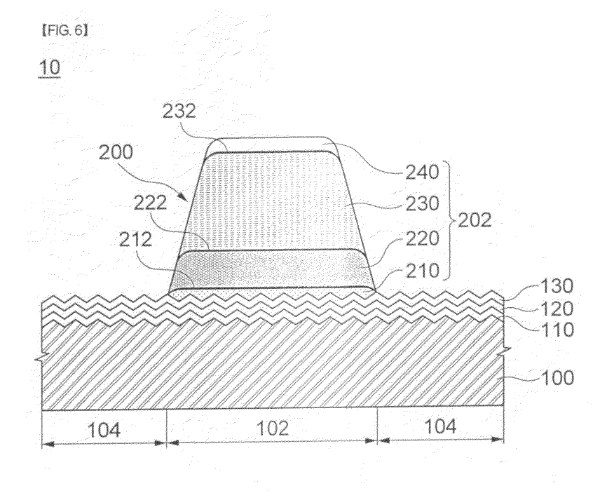

FIG. 2 is a flow chart showing a method for manufacturing a solar cell according to an embodiment of the present invention. FIGS. 3 to 6 are diagrams for explaining a method for manufacturing a solar cell according to an embodiment of the present invention.

Referring to FIGS. 2 and 3, a substrate 100 for manufacturing a solar cell may be prepared (S110). For example, the preparing the substrate 100 may prepare a silicon wafer. The silicon wafer may include a first region 102 on which a conductive electrode pattern 200 (in FIG. 1) is formed and second regions 104 other than the first region 102. The second region 104 may be a region to define a line width of the conductive electrode pattern 200. For example, the second region 104 may be controlled to have a width of approximately 80 μm or less.

A light receiving surface 110 of the silicon wafer may be textured. Therefore, the light receiving surface 110 of the substrate 100 may have a predetermined rugged structure. Herein, the silicon wafer may be controlled to have a minimum thickness so as to reduce the manufacturing costs thereof. For example, the thickness of the silicon wafer may be controlled to be 180 μm or less. The present embodiment describes a case in which the substrate 100 is a silicon wafer by way of example, but the substrate 100 may use various kinds of substrate. For example, the substrate 100 may use a glass substrate or a plastic substrate.

Forming a PN junction layer 120 on the light receiving surface of the substrate 100 and forming a transparent electrode layer 130 on the PN junction layer 120 may be sequentially performed. The forming the PN junction layer 120 may include injecting impurity semiconductors into the silicon wafer. For example, the silicon wafer is a P-type semiconductor substrate and the PN junction layer 120 may be formed by injecting N-type impurity ions into the P-type semiconductor substrate. The forming the transparent electrode layer 130 may include forming a transparent conductive oxide (TCO) on the PN junction layer 120.

Referring to FIGS. 2 and 4, a first metal layer 210 may be formed on the substrate 100 (S120). As an example, the forming the first metal layer 210 may include applying a first conductive ink to the first region 102 of the substrate 100 by an inkjet printing method. The first conductive ink may be ink including any one metal ions of transition metals. As an example, the first conductive ink may use an inkjet printing ink including silver (Ag). Herein, the inkjet printing method forms a metal wiring on the substrate 100 in a non-contact scheme, such that physical pressure may not be applied to the substrate 100 at the time of forming the first metal layer 210. Therefore, the present invention applies the first conductive ink to the substrate 100 by the inkjet printing method, thereby making it possible to form the first metal layer 210 on the first region 102, without physical damage on the substrate 100. In particular, in the present invention physical pressure is not applied to the substrate 100, such that the substrate 100 can be prevented from being damaged even though the thickness of the substrate 100 is controlled to be 180 μm or less, as compared to a technology that applies physical pressure to the substrate 100 such as screen printing.

Referring to FIGS. 2 and 5, a second metal layer 220 may be formed on the first metal layer 210 by using the first metal layer 210 as a seed layer (S130). As an example, the forming the second metal layer 220 may include forming a first plating rate reducing layer 211 over the substrate 100 and performing a plating process plating the second metal layer 220 on the first metal layer 210.

The forming the first plating rate reducing layer 211 may include forming a predetermined carboxylic acid based thin layer over the substrate 100. As an example, the forming the first plating rate reducing layer 211 may include applying an organic acid over the substrate 100. The applied organic acid can remove impurities remaining on the first metal layer 210 of the substrate 100. The forming the first plating rate reducing layer 211 may be made by performing any one of spray coating, brushing, dipping, spin coating, inkjet printing, and roll-to-roll printing.

The organic acid may use at least any one of oxalic acid, oxalacetic acid, fumaric acid, malic acid, succinic acid, acetic acid, butyric acid, palmitic acid, tartaric acid, ascorbic acid, uric acid, sulfonic acid, sulfinic acid, phenol, formic acid, citric acid, isocitric acid, α-ketoglutaric acid, succinic acid, and nucleic acid.

A first plating process of forming the second metal layer 220 including any one of transition metals on the first metal layer 210 may be performed by using the first metal layer 210 as a seed layer. As an example, the first plating process may be a process forming a nickel plating layer including nickel (Ni) on the first metal layer 210. The nickel plating layer may be a plating layer grown by using the silver layer as a seed layer.

Meanwhile, the organic acid may reduce efficiency of a plating process for the second region 104 when the first plating process is performed. For example, the plating process may use various kinds of catalyst so as to expedite a plating process. At this time, the organic acid reduces action of the catalyst, thereby making it possible to reduce the efficiency of the plating process for the substrate 100. In this case, the plating rate reducing layer 211 can reduce the efficiency of plating process not only on the second region 104 but also on the first region 102. However, since the plating rate for the first metal layer 210 is much faster than the plating rate for the second region 104, the degradation in efficiency of forming the second metal layer 220 on the first metal layer 210 due to the organic acid may be insignificant. Therefore, the organic acid can improve bonding reliability between the first metal layer 210 and the second metal layer 220 by removing foreign substances from the first metal layer 210 and prevent a plating layer from being formed on the second region 104 of the substrate 100.

Through the plating process as described above, the first metal layer 210 and the second metal layer 220 that are limited to the first region 102 and are stacked each other may be formed on the substrate 100. In other words, the silver layer and the nickel layer, sequentially stacked, may be formed on the first region 102 of the substrate 100. At this time, the organic acid remains between the first metal layer 210 and the second metal layer 220, such that a predetermined first organic compound thin layer 212 (in FIG. 6) may be formed.

Referring to FIGS. 2 and 6, a third metal layer 230 and a fourth metal layer 240 may be sequentially formed on the second metal layer 220 (S140). The third metal layer 230 and the fourth metal layer 240 may be formed, substantially similar to the process of forming the second metal layer 220.

For example, the forming the third metal layer 230 may include forming a second plating rate reducing layer (not shown) over the substrate, and performing a second plating process that forms the third metal layer 230 on the second metal layer 220 by using the second metal layer 220 as a seed layer. The second plating rate reducing layer may use a predetermined organic acid. The third metal layer 230 may be made of any one of the transition metals. As an example, the third metal layer 230 may be a copper layer including copper (Cu). In this case, the third metal layer 230 may be formed to occupy the largest volume of the entire volume of the conductive electrode pattern 200.

The forming the fourth metal layer 240 may include forming a third plating rate reducing layer (not shown) over the substrate, and performing a third plating process that forms the fourth metal layer 240 on the third metal layer 230 by using the third metal layer 230 as a seed layer. The third plating rate reducing layer may use a predetermined organic acid. The fourth metal layer 240 may be made of any one of transition metals and the fourth metal layer may be, for example, a tin layer including tin (Sn).

Through the second and third plating processes, a second organic compound thin layer 222 may be formed between the second and third metal layers 220 and 230 due to the remaining second plating rate reducing layer, and a third organic compound thin layer 232 may be formed between the third and fourth metal layers 230 and 240 due to the remaining third plating rate reducing layer.

Meanwhile, the aforementioned embodiment describes a case in which the second to fourth plating layers 220, 230, and 240 are formed by performing a plating process by way of example, but the second to fourth plating layers 220, 230, and 240 may also be formed by an inkjet printing method, similar to the first plating layer 210. For example, as another embodiment of the present invention, the first to fourth plating layers 210, 220, 230, and 240 repeatedly perform an inkjet printing method on the first region 102 of the substrate 100, thereby making it possible to form the conductive electrode pattern 200. Therefore, a method for manufacturing a solar cell according to another embodiment of the present invention can complete the forming of the conductive electrode pattern 200 having the hetero-metal layer stacking structure 202 by an inkjet printing method.

As described above, the method for manufacturing the solar cell according to the present invention selectively performs the inkjet printing method and the plating process, thereby making it possible to form the conductive electrode pattern 200 having the hetero-metal layer multi-layer structure 202 on the substrate 100. Herein, the conductive electrode pattern 200 can have a structure in which the content of silver (Ag), which is relatively expensive, is decreased while maintaining the electrode characteristics. Therefore, the method for manufacturing the solar cell according to the present invention reduces the used amount of silver in the conductive electrode pattern 200, thereby making it possible to manufacture the solar cell 10 reducing manufacturing costs.

In addition, the method for manufacturing the solar cell according to the present invention can form the conductive electrode pattern 200, which is used as an electrode of a solar cell, on the substrate 100 by an inkjet printing method. Therefore, the method for manufacturing the solar cell according to the present invention can form the conductive electrode pattern 200 without applying physical pressure to the substrate 100 to make the thickness of the substrate 100 thin, thereby making it possible to manufacture the solar cell 10 reducing manufacturing costs and improving integration.

In addition, the method for manufacturing the solar cell according to the present invention forms the conductive electrode pattern 202 formed of different metal layers 210, 220, 230, and 240 on the substrate 100 and performs a predetermined organic acid processing process at the time of plating process forming the metal layers 220, 230, and 240. The organic acid processing process can remove foreign substances from the metal layers 210, 220, 230, and 240 and prevent a plating layer from being formed in the electrode non-forming region (that is, second region: 104) of the substrate 100. Therefore, the method for manufacturing the solar cell according to the present invention prevents foreign substances from being interposed between the metal layers 210, 220, 230, and 240 to improve bonding reliability between the metal layers 210, 220, 230, and 240, thereby making it possible to manufacture the solar cell 10 improving the electrode characteristics.

According to the present invention, the conductive electrode pattern may have the hetero-metal layer stacking structure formed of different kinds of metal layers, and the metal layer stacking structure may have a structure in which the content of the silver layer, which is expensive, is decreased and the content of the copper layer, which is relatively inexpensive and has excellent electrical conductivity, is increased, while maintaining the electrode characteristics. Therefore, the conductive electrode pattern according to the present invention can reduce the manufacturing costs thereof, while maintaining or improving the electrode characteristics thereof.

According to the present invention, the solar cell includes a substrate and a conductive electrode pattern used as an electrode wiring of the solar cell, wherein the conductive electrode pattern may have a hetero-metal layer stacking structure formed of different kinds of metal layers. The metal layer stacking structure may have a structure in which the content of the silver layer, which is expensive, is decreased and the content of the copper layer, which is relatively inexpensive and has excellent electrical conductivity, is increased, while maintaining the electrode characteristics. Therefore, according to the present invention, the solar cell reduces the forming costs of the conductive electrode pattern, thereby making it possible to reduce the manufacturing costs thereof.

According to the present invention, the solar cell may have a structure in which the thickness of the substrate for manufacturing the solar cell is reduced to 180 μm or less, thereby making it possible to reduce the used amount of silicon, a material of the substrate, Therefore, according to the present invention, the solar cell includes the substrate having a minimum thickness on which the conductive electrode pattern can be formed, thereby making it possible to improve integration and reduce manufacturing costs thereof.

The present invention has been described in connection with what is presently considered to be practical exemplary embodiments. Although the exemplary embodiments of the present invention have been described, the present invention may be also used in various other combinations, modifications and environments. In other words, the present invention may be changed or modified within the range of concept of the invention disclosed in the specification, the range equivalent to the disclosure and/or the range of the technology or knowledge in the field to which the present invention pertains. The exemplary embodiments described above have been provided to explain the best state in carrying out the present invention. Therefore, they may be carried out in other states known to the field to which the present invention pertains in using other inventions such as the present invention and also be modified in various forms required in specific application fields and usages of the invention. Therefore, it is to be understood that the invention is not limited to the disclosed embodiments. It is to be understood that other embodiments are also included within the spirit and scope of the appended claims.

What is claimed is:

1. A conductive electrode pattern, comprising:
a lower metal layer and an upper metal layer that are vertically disposed on a substrate,
wherein any one of the lower metal layer and the upper metal layer includes silver (Ag) and the other one of the lower metal layer and the upper metal layer includes a metal of transition metals, different from that of the lower metal layer.

2. The conductive electrode pattern according to claim 1, wherein the lower metal layer includes silver, and
the upper metal layer includes at least any one of titanium (Ti), vanadium (V), chrome (Cr), manganese (Mn), iron (Fe), cobalt (Co), nickel (Ni), copper (Cu), silver (Ag), gold (Au), and iron (Fe).

3. The conductive electrode pattern according to claim 1, wherein the lower upper metal layer is formed by using the lower metal layer as a seed layer.

4. The conductive electrode pattern according to claim 1, further comprising an organic compound thin layer interposed between the upper metal layer and the upper metal layer.

5. The conductive electrode pattern according to claim 4, wherein the organic compound thin layer includes an organic acid.

6. The conductive electrode pattern according to claim 4, wherein the organic compound thin layer includes at least any one of oxalic acid, oxalacetic acid, fumaric acid, malic acid, succinic acid, acetic acid, butyric acid, palmitic acid, tartaric acid, ascorbic acid, uric acid, sulfonic acid, sulfinic acid, phenol, formic acid, citric acid, isocitric acid, α-ketoglutaric acid, succinic acid, and nucleic acid.

7. The conductive electrode pattern according to claim 1, further comprising a barrier layer interposed between the lower metal layer and the upper metal layer.

8. The conductive electrode pattern according to claim 7, wherein the barrier layer includes nickel (Ni).

9. The conductive electrode pattern according to claim 7, wherein the barrier layer is a plating layer formed by using the lower metal layer as a seed layer.

10. The conductive electrode pattern according to claim 1, further comprising a top metal layer that is stacked on the upper metal layer,
wherein the top metal layer is used as a medium for connecting the conductive electrode pattern to an external electronic apparatus.

11. The conductive electrode pattern according to claim 10, wherein the top metal layer includes tin (Sn).

12. The conductive electrode pattern according to claim 10, wherein the top metal layer is a plating layer formed by using the upper metal layer as a seed layer.

13. A conductive electrode pattern used as an electrode of a solar cell, wherein the conductive electrode pattern has a hetero-metal layer stacking structure formed of different metal layers.

14. The conductive electrode pattern according to claim 13, wherein the hetero-metal layer stacking structure includes metal layers made of different metals among transition metals.

15. The conductive electrode pattern according to claim 13, wherein the hetero-metal layer stacking structure includes:
a silver (Ag) layer disposed adjacent to the silicon substrate; and
a copper (Cu) layer stacked on the silver layer, the thickness of the silver layer being thinner than that of the copper layer.

16. The conductive electrode pattern according to claim 15, wherein the hetero-metal layer stacking structure further includes a nickel layer interposed between the silver layer and the copper layer,
the thickness of the nickel layer being thicker than that of the silver layer and being thinner than that of the copper layer.

17. The conductive electrode pattern according to claim 15, wherein the hetero-metal layer stacking structure further includes a tin layer that covers the copper layer,
the thickness of the tin layer being thicker than that of the silver layer and being thinner than that of the copper layer.

18. The conductive electrode pattern according to claim 13, wherein the hetero-metal layer stacking structure includes metal layers made of different metals and stacked each other,
a bottom metal layer of the metal layers being a metal layer formed by applying a conductive ink, and
metal layers disposed on the bottom metal layer among the metal layers being plating layers formed by using metal layers below the metal layers as seed layers.

19. The conductive electrode pattern according to claim 13, wherein the hetero-metal layer stacking structure includes:
metal layers made of different metals; and
an organic compound thin layer interposed between the metal layers, the organic compound thin layer including an organic acid.

20. The conductive electrode pattern according to claim 19, wherein the organic acid includes at least any one of oxalic acid, oxalacetic acid, fumaric acid, malic acid, succinic acid, acetic acid, butyric acid, palmitic acid, tartaric acid, ascorbic acid, uric acid, sulfonic acid, sulfinic acid, phenol, formic acid, citric acid, isocitric acid, α-ketoglutaric acid, succinic acid, and nucleic acid.

21. A solar cell, comprising:
a substrate that has a light receiving surface on which an external light is incident; and
a conductive electrode pattern that is disposed on the light receiving surface of the substrate,
wherein the conductive electrode pattern is formed of different metal layers.

22. The solar cell according to claim 21, wherein any one of the metal layers includes silver (Ag), and others of the metal layers include any one of titanium (Ti), vanadium (V), chrome (Cr), manganese (Mn), iron (Fe), cobalt (Co), nickel (Ni), copper (Cu), silver (Ag), gold (Au), iron (Fe), tin (Sn), lead (Pb), and zinc (Zn).

23. The solar cell according to claim 21, wherein the metal layers include:
a silver (Ag) layer that is disposed adjacent to the silicon substrate; and
a copper (Cu) layer that is stacked on the silver layer, the thickness of the silver layer ranging from 0.1 μm to 3 μm, the thickness of the copper layer ranging from 25 μm to 29 μm.

24. The solar cell according to claim 23, wherein the metal layers further include a nickel layer that is interposed between the silver layer and the copper layer,
the thickness of the nickel layer ranging from 2 μm to 5 μm.

25. The solar cell according to claim 23, wherein the metal layers further include a tin layer that covers the copper layer, the thickness of the tin layer ranging 0.5 μm to 2.5 μm.

26. The solar cell according to claim 21, wherein a bottom metal layer of the metal layers is a metal layer formed by applying a conductive ink onto the substrate, and
metal layers stacked on the bottom metal layer among the metal layers are plating layers formed by using metal layers below the metal layers as seed layers.

27. The solar cell according to claim 21, wherein a thickness of the substrate is 180 μm or less,
a line width of the conductive electrode pattern is 80 μm or less, and
a thickness of the conductive electrode pattern is 30 μm or less.

28. The solar cell according to claim 21, wherein the hetero-metal layer stacking structure includes organic compounds thin layer interposed between the metal layers,
the organic compound thin layer including an organic acid.

29. The solar cell according to claim 28, wherein the organic acid includes at least any one of oxalic acid, oxalacetic acid, fumaric acid, malic acid, succinic acid, acetic acid, butyric acid, palmitic acid, tartaric acid, ascorbic acid, uric acid, sulfonic acid, sulfinic acid, phenol, formic acid, citric acid, isocitric acid, α-ketoglutaric acid, succinic acid, and nucleic acid.
